(19) United States
(12) Patent Application Publication
(10) Pub. No.: US 2005/0127441 A1
(43) Pub. Date: Jun. 16, 2005

(54) Body contact layout for semiconductor-on-insulator devices

(75) Inventors: Donald W. Plass, Pleasant Valley, NY (US); Kenneth J. Reyer, Stormville, NY (US)

Correspondence Address: Andrew J. Wojnicki, Jr.;Intellectual Property Law, IBM Corporation, MS P386, 2455 South Road, Poughkeepsie, NY, 12601, US

(73) Assignee: International Business Machines Corporation, Armonk, NY (US)

(21) Appl. No.: 10/733,680

(22) Filed: Dec. 11, 2003

(51) Int. Cl. H01L 27/01

(52) U.S. Cl. 257/347

(57) ABSTRACT

A method and structure is provided for an improved body contact layout for semiconductor-on-insulator (SOI) devices. In one embodiment, an insulated gate field effect transistor and method for fabrication of such a transistor is provided. The insulated gate field effect transistor includes a source, a drain, and a channel formed in a layer of a single-crystal semiconductor. The layer is disposed over and insulated from a bulk semiconductor layer of a substrate by a buried insulator layer. A gate conductor is disposed in an annular pattern overlying the channel, such that the gate conductor surrounds one of the source and drain disposed to the inside of the annular pattern, the other of the source and drain being disposed to the outside of the annular pattern. A second conductive pattern is connected to the annular pattern of the gate conductor. A conductive body contact is also disposed in the vicinity of the second conductive pattern.

### BACKGROUND OF THE INVENTION

The invention relates to a semiconductor structure and processing method, and more particularly to a structure and method of fabricating a silicon-on-insulator device having a body contact.

Speed is a key aspect of operational performance of integrated circuits. In recent years, enhanced fabrication techniques including silicon-on-insulator (SOI) technology have been introduced. SOI technology is becoming increasingly important since it assists in lowering the capacitance of transistors, enabling greater switching speeds. When FETs are formed in bulk substrates, the junction between the body of the transistor (the portion of the transistor immediately below the gate including the transistor channel) and the semiconductor material the body results in significant capacitance. In SOI substrates, active devices such as field effect transistors (FETs) are formed in a relatively thin layer of semiconductor material (Si) overlying a buried layer of insulating material such as a buried oxide (BOX). SOI technology eliminates the junction capacitance by electrically isolating the body of the transistor from the substrate semiconductor material below. With the presence of the BOX layer under the transistor body, the gate dielectric on top, and the source and drain regions on the sides, the body of the SOI FET is in fact, electrically isolated.

The electrically isolated body of a transistor formed in an SOI substrate is known as a “floating body” because the body floats at a potential which varies according to various conditions in which the transistor is operated, wherein such potential is usually not known in advance. In consequence, the threshold voltage V_{T} of the transistor is subject to variation, also to an extent that is usually not known in advance. The threshold voltage V_{T} is the voltage at which a FET transitions from an ‘off’ state to an ‘on’ state. FETs are fabricated as either n-channel type FETs (NFETs) or p-channel type FETs (PFETs). Using the NFET as an example of an FET, the threshold voltage VT may be lowered, causing the NFET to turn on at too low a voltage, early within a switching cycle. This may cause an early or false detection signal for rising signal transitions. Conversely, for falling signal transitions, detection comes later than expected. In addition, a lower value of the low voltage is required to keep the subthreshold leakage current tolerably low. Alternatively, the threshold voltage V_{T} may increase as a result of charge accumulation, causing the NFET to turn on late for rising signal transitions and early in the case of falling signal transitions.

While such variations in the threshold voltage are usually tolerable when the FET is used in a digital switching element such as an inverter or logic gate, FETs used for amplifying signals, especially small swing signals, need to have a stable threshold voltage.

The solution is to provide a body contact for the FET formed on a SOI substrate. A body contact is an electrically conductive contact made to the body of the transistor to provide, inter alia, a low-resistance path for the flow of charge carriers to and from the transistor body.

FIG. 1 is a plan view illustrating a prior art FET formed in a SOI substrate, the FET having a body contact. FIG. 1 illustrates a FET having two fingers 102 which extend in a direction of the length 115 of an active area 110. The two fingers are placed parallel to each other, dividing the width 120 of the active area 110 into three parts, the two sources 113 provided between the fingers 110 and the outer edges of the active area 110 and the drain 114 provided between the two fingers 102. The two-finger design is advantageous because it provides increased current drive over a one-finger FET design occupying an active area of the substrate having the width 120.

The body 160 (FIG. 2) of the FET is disposed under the gate conductor 112, (not shown in the top-down view of FIG. 1). FIG. 2 is a cross-sectional view of the FET through 2-2 of FIG. 1. As shown in FIG. 2, current flows across the channel 120 between the source 113 and drain 114 regions when a transistor is properly biased by a voltage on the gate conductor 112. The channel 120 is a thin region of the body 160 directly below the gate conductor 112 which controls the flow of current between the source and drain regions 113 and 114. An insulator region 230 is also provided that separates the FET structure 100 shown in FIGS. 1 and 2 from other FETs structures on the same chip or substrate.

As shown in FIG. 3, the body contact 170 is provided on one side of the gate conductor 112 with the drain 114 region provided on the other side of the gate conductor 112. The body contact has p+ doping in order to provide a conductive path to the body 160 of the NFET. This differs from the n+ type doping used for the source and drain regions 113 and 114.

The use of body contacts are particularly helpful in the prior art when used with current sources, current mirror circuits or when used in conjunction with sense amplifiers when data signals need to be amplified. In addition, the body contact designs are used in partially depleted SOI FET devices in order to minimize the floating charge body effects.

Unfortunately, however, despite the advantages they provided by prior art, body contact designs have been used sparingly because they increase the area of the transistor and add capacitance, which increase chip area and degrade circuit performance.

The increase in surface area is best viewed in the top down depiction of FIG. 1, where a large gate conductor area 112 is provided and a large area is set aside for body contact 170. The enlarged area, in this case, adds to the capacitance since it is not used for driving current. Despite being in capacitive contact with the active area, this area does not lie in the area between the source and drain region so no current is driven through it. The increase in capacitance impacts the switching speed, and is also related to the increase in the area of the gate conductor. To counter the effects of increased capacitance the driver current would need to be increased to maintain the original switching speed. Besides being difficult to accomplish, such would cause an undesirable increase in power dissipation.

An alternative solution has been provided by the prior art to reduce capacitance caused by the large gate conductor pattern. FIG. 4 is a plan view illustrating a body-contacted FET having reduced gate conductor area 412. Due to its reduced size, the gate conductor 412 no longer separates the source regions of the active area from the body contact 470, as it did in the FET shown in FIG. 1. As a result, the source region is no longer isolated from the body contact area, such that the voltages applied to the source and the body contact must be kept at the same level, e.g. ground.

One difficulty with the use of the body contact designs, whether having the design characteristics FIG. 1 or FIG. 4, is tolerance to overlay error. A shift in the direction of the length 115 (FIG. 1) of the active area 110 increases or decreases the length of the gate conductor fingers 102 over the active area. This either increases or decreases the current drive, respectively. Small devices, in which the gate conductor fingers are not very long from the start, may experience significant change in the current drive as overlay error causes a proportionally large change in the length of the gate conductor fingers of the active area. As a result, in such case, overlay error in the manufacturing process within a normally expected range can cause considerable variations in the current drive.

Consequently, an improved structure and fabrication method are needed for providing a body-contacted FET which is tolerant to overlay errors in fabrication.

### SUMMARY OF THE INVENTION

A method and structure is provided for an improved body contact layout for semiconductor-on-insulator (SOI) devices. In one embodiment, an insulated gate field effect transistor and method for fabrication of such a transistor is provided. The insulated gate field effect transistor includes a source, a drain, and a channel formed in a layer of a single-crystal semiconductor. The layer is disposed over and insulated from a bulk semiconductor layer of a substrate by a buried insulator layer. A gate conductor is disposed in an annular pattern overlying the channel, such that the gate conductor surrounds one of the source and drain disposed to the inside of the annular pattern, the other of the source and drain being disposed to the outside of the annular pattern. A second conductive pattern is connected to the annular pattern of the gate conductor. A conductive body contact is also disposed in the vicinity of the second conductive pattern.

### BRIEF DESCRIPTION OF THE DRAWINGS

FIG. 1 is a top down depiction of a prior art FET using SOI technology having a first body contact design;

FIG. 2 is a cross sectional depiction of the FET of FIG. 1;

FIG. 3 is another cross sectional depiction of the FET of FIG. 1, cut across a different line than that of FIG. 2 to provide an alternate view;

FIG. 4 is a top down depiction of a prior art FET using SOI technology having an alternate body contact design;

FIG. 5 is a top down depiction of a first embodiment of the present invention;

FIG. 6 is a cross section depiction of the embodiment provided in FIG. 5;

FIGS. 7A and 7B each illustrate depictions of a SOI substrate;

FIGS. 8 though 15 illustrate an embodiment of a method of fabricating a body-contacted transistor;

FIG. 16 illustrates a body-contacted transistor according to a self-aligned embodiment;

FIG. 17 is a top down depiction of a transistor according to a further embodiment of the invention; and

FIG. 18 is a top down depiction of a transistor according to another embodiment of the invention.

### DETAILED DESCRIPTION

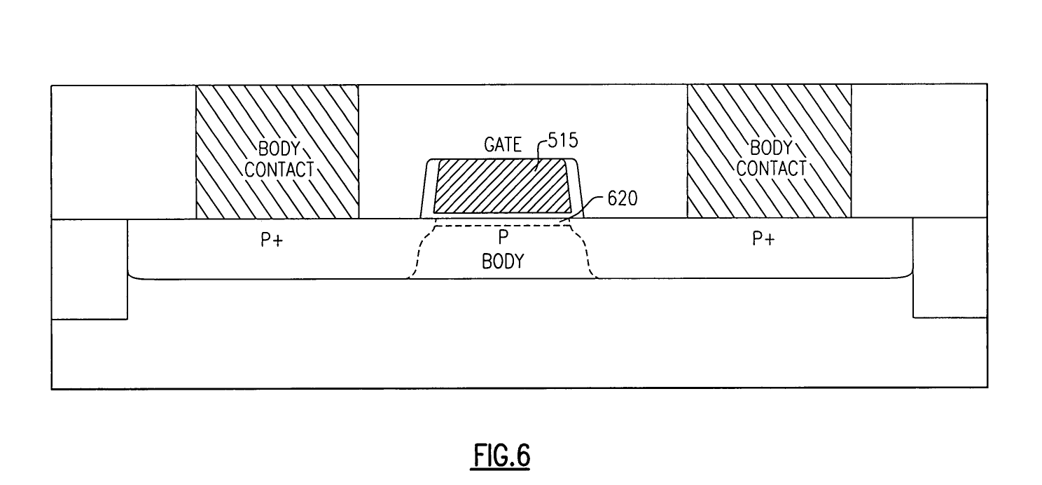

FIG. 5 is a top down view of an embodiment of the present invention. FIG. 5 illustrates an insulated gate field effect transistor 500 formed on a SOI substrate and having a two finger design. The two prongs of the finger as shown at 502 are electrically connected to one another to form an annular gate conductor structure 515. A source 513 region, a drain 514 region, and a channel are all formed in active area 550. Because the channel is not viewable in a top-down depiction as provided by FIG. 5, a cross-sectional view is provided in FIG. 6.

FIG. 6 is a cross-sectional view of the embodiment of FIG. 5. As illustrated in FIGS. 5 and 6, the gate conductor 515 which is disposed in an annular pattern (visible in FIG. 5) overlays the channel 620 (illustrated in FIG. 6), such that the gate conductor 515 surrounds the drain 514 disposed to the inside of the annular pattern. The source 513 is disposed to the outside of the annular pattern.

In embodiment of FIG. 5, the gate conductor 515 is connected to a second conductive pattern electrically connected to the annular pattern 517. A conductive body contact 570 is also provided and disposed in the vicinity of this second pattern or extension 518. In a preferred embodiment, the annular portion 515 includes a pair of parallel portions oriented in a first direction substantially parallel to an edge of the active area. The annular portion further includes angled portions which are angled relative to this first direction. The angles are preferably between 30 degrees and 60 degrees, however an angle of 45 degrees will provide maximum current flow advantages.

The gate conductor 515 of FIGS. 5 and 6 preferably includes a stack of one or more conductive layers and may optionally include a top insulating layer. The source and drain regions 513 and 514 are created by implants performed to respective portions of the active area 550 that are to become source and drain regions 513 and 514. The type of doping determines whether the FET is a PFET as opposed to an NFET transistor is to be used. In the particular embodiment of FIGS. 5 and 6, an NFET is provided in which the body contact 570 is doped with p-type impurities. If it were a PFET instead of an NFET, the body contact 570 would be doped instead with n-type impurities.

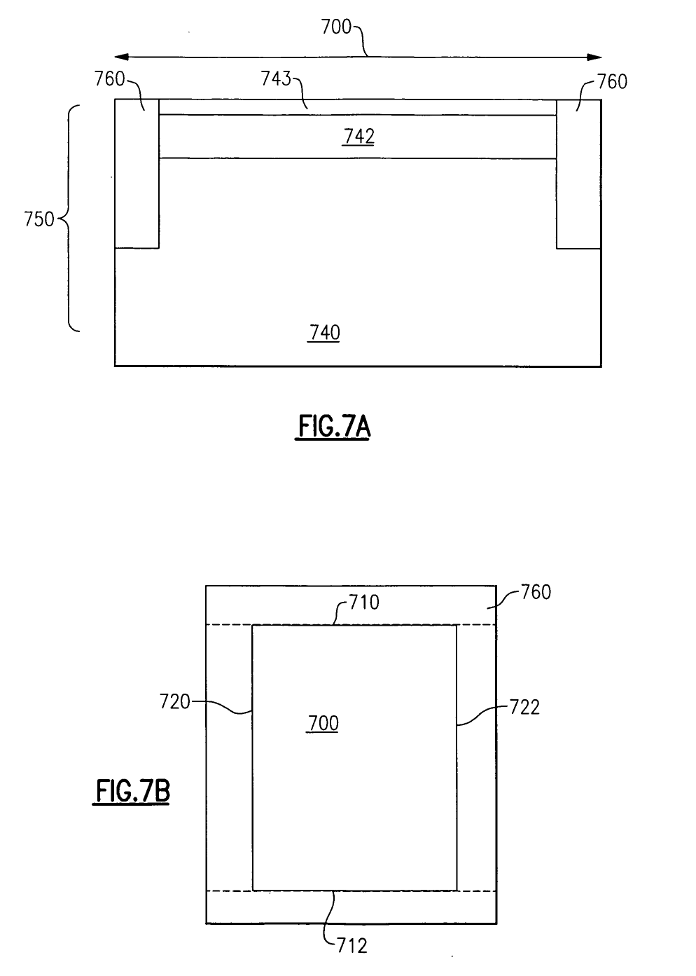

FIGS. 7A through 15 illustrate a method of fabricating the FET shown in FIGS. 5 and 6. FIG. 7A is a cross-sectional view of a silicon-on-insulator (SOI) substrate 750. As shown in FIG. 7A, an active area 700 of the SOI substrate includes a relatively thin layer 743 of a single-crystal semiconductor overlying a buried oxide (BOX) layer 742, which in turn, overlies a bulk portion 742 of the substrate 750. Such silicon-on-insulator (SOI) substrate is an example of semiconductor-on-insulator substrates which can include any one of several semiconductor materials other than silicon as the material of the upper single-crystal layer and the bulk portion 740. Isolation structures such as trench isolations 760 are further provided, which bound the active area 700. FIG. 7B is a top down view of the SOI substrate shown in FIG. 7A. Active area 700 is the area between isolation structures 760. In an embodiment, the isolation structures 760 bound the active area 700 on all sides. However, in another embodiment, the isolation structures bound the active area 700 only on two sides, such as those shown at the top edge 710 and bottom edge 712 of FIG. 7B, leaving the left side 720 and the right side 722 of the active area 700 non-isolated as common regions between the sources of FETs that are disposed in side-to-side relation with each other.

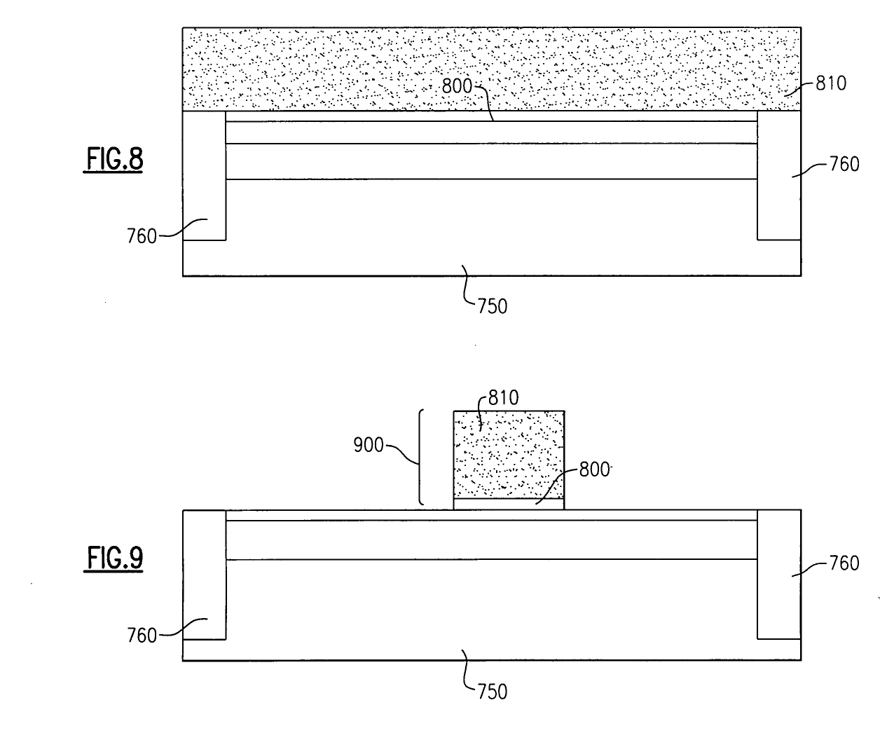

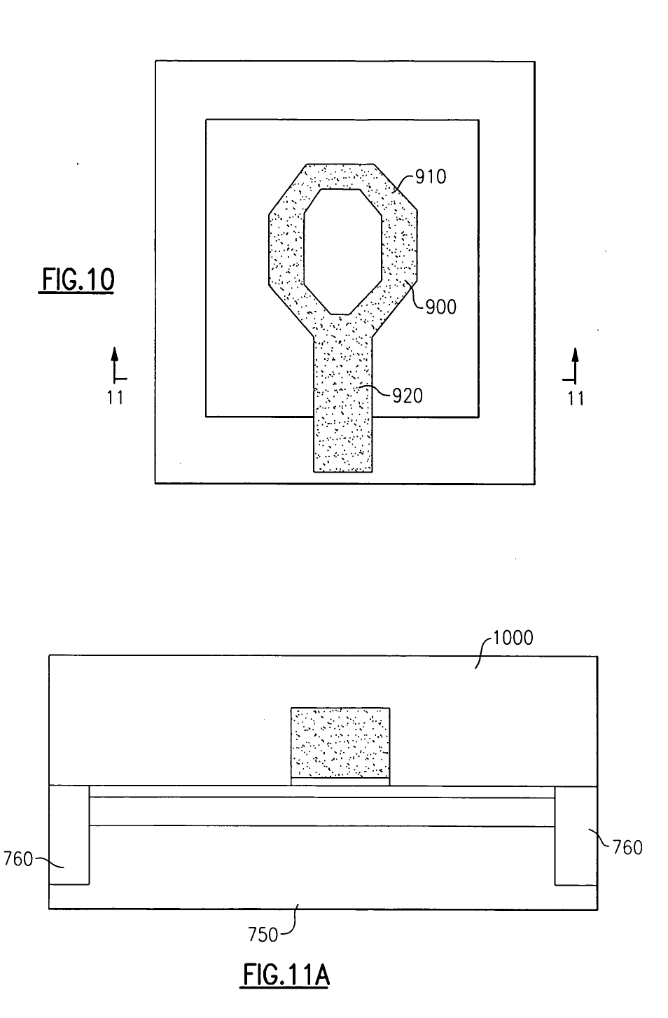

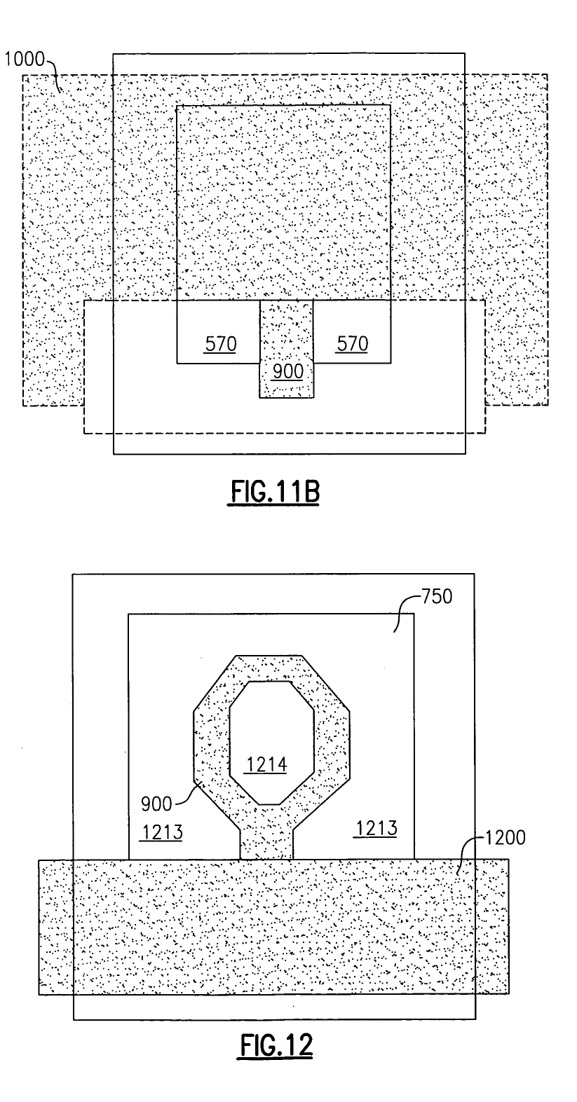

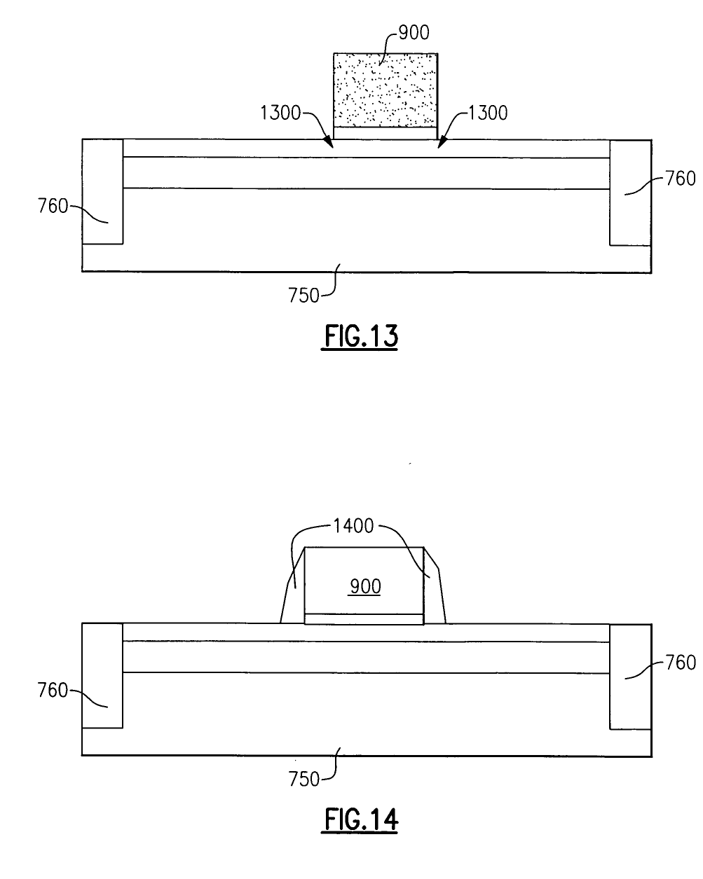

Thereafter, steps are performed to begin forming the body-contacted field effect transistor illustrated in FIGS. 5 and 6. FIGS. 8 through 15 illustrate a first embodiment in which the body contact and contacts for the source and drain are formed in a manner that is not self-aligned to the gate conductor. A second embodiment will be described thereafter in which such contacts are formed in a self-aligned manner.

As shown in FIG. 8, a gate dielectric 800 is formed by deposition or grown on the substrate 750. The gate dielectric 800 may include an oxide such as silicon dioxide, a nitride such as silicon oxynitride or other similar material. As shown in FIG. 8, a layer 810 of polysilicon is then deposited as a gate material on the gate dielectric 800.

The next processing step is provided in the cross sectional depiction of FIG. 9. As shown in FIG. 9, a gate stack 900 including the polysilicon material 810 and the gate dielectric 800 are patterned together by a vertical etch process, such as a reactive ion etch (RIE).

FIG. 10 is a top down view illustrating the resulting patterned gate stack 900 showing the annular pattern 910 and a second pattern 920 extending from the annular pattern.

FIG. 11A is a cross-sectional view of the structure shown in FIG. 10 through lines 11-11. As shown in FIG. 11A, a layer of photoresist, anti-reflective coating or other similar coating that can be used to protect areas from impurity doping and is distinguishable from the polysilicon material used in the gate stack 900 is blanket deposited over the structure. This layer is shown at 1000. The layer 1000 has to be easily removable because after the blanket deposition of the layer, layer 1000 is selectively removed using etching techniques, to expose the areas that will be pattered to eventually become the body contact area of FIGS. 5 and 6.

FIG. 11B is a top down view illustrating the next processing stage. In FIG. 11B, layer 1000 is removed from those areas that are to become the body contact region 570, while remaining in the areas shown including over the annular portion 910 of the gate stack 900. The body contact regions 570 are now formed by a p+ ion implant of boron through the opening shown in the masking material 1000.

Next, as shown in FIG. 12, the masking layer 1000 is removed from the remaining areas, and a new masking layer 1200 is patterned to cover the body contact region, while exposing the areas that will become the source and drain regions of the transistor. The top down depiction of FIG. 12 illustrates the exposed areas 1213 and 1214 that will become the drain and source areas 513 and 514 in FIGS. 5 and 6, as separated by the gate stack 900.

FIG. 13 is a cross sectional view illustrating an ion implant 1300 performed thereafter for the purpose of forming halos and/or lightly doped extensions in areas where source and drain regions will be formed. Sidewall spacers are then formed on sidewalls of the gate stack 900, as illustrated in FIG. 14. The spacers are formed of any suitable dielectric material such as silicon dioxide, silicon nitride and/or silicon oxynitride, among others.

FIG. 15 is cross sectional view illustrating a subsequent processing step. In FIG. 15, an n+ ion implant is performed to the source and drain regions, as shown by arrows 1500. Such implant is followed by deposition of an interlevel dielectric and annealing to drive implanted dopant ions into the semiconductor material of the SOI layer 743. Thereafter, contact vias are etched in the interlevel dielectric and the body contact and source and drain contacts are formed in the contact vias to provide electrical connection to the transistor. The resultant transistor is illustrated in FIGS. 5 and 6.

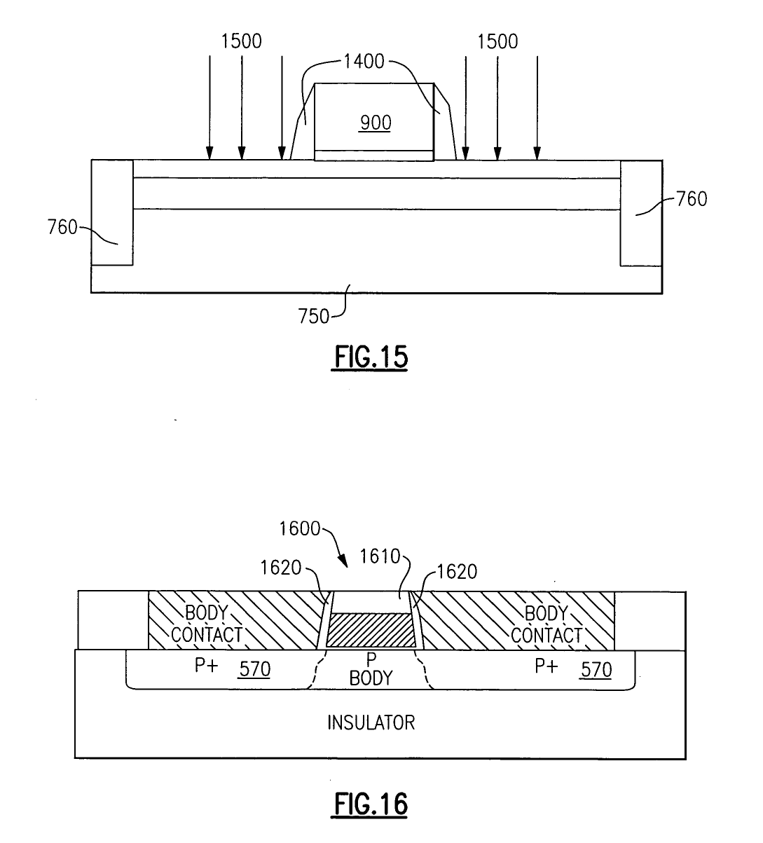

In another embodiment, as illustrated in FIG. 16, the body contact is formed in a self-aligned manner to the gate conductor. In such self-aligned process, a gate stack 1600 including an insulating cap 1610 is patterned, generally as shown in FIG. 16, however initially without sidewall spacers. Then, the masking process of FIG. 11B is used to mask the active area except in the region 570 where the body contact will be located. A doping process is then performed such as a boron ion implant to achieve a relatively high p+ dopant concentration (e.g. 10¹⁸ cm⁻³) in the body contact region 570. Insulating spacers are then formed on sidewalls of the gate conductor where exposed in the body contact region 570. The insulating spacers are preferably formed of silicon dioxide, silicon nitride, or a combination thereof. After the insulating spacers are formed, a body contact is formed by depositing at least one material selected from heavily doped polysilicon, metals and conductive metal compounds including metal silicides. Thereafter, the body contact region 570 is masked, and processing continues as described above with respect to FIGS. 12 et seg.

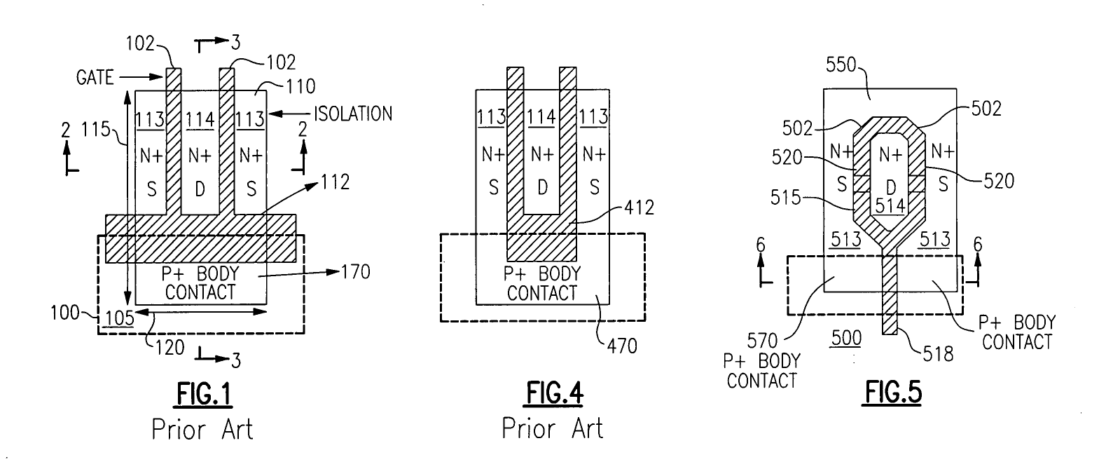

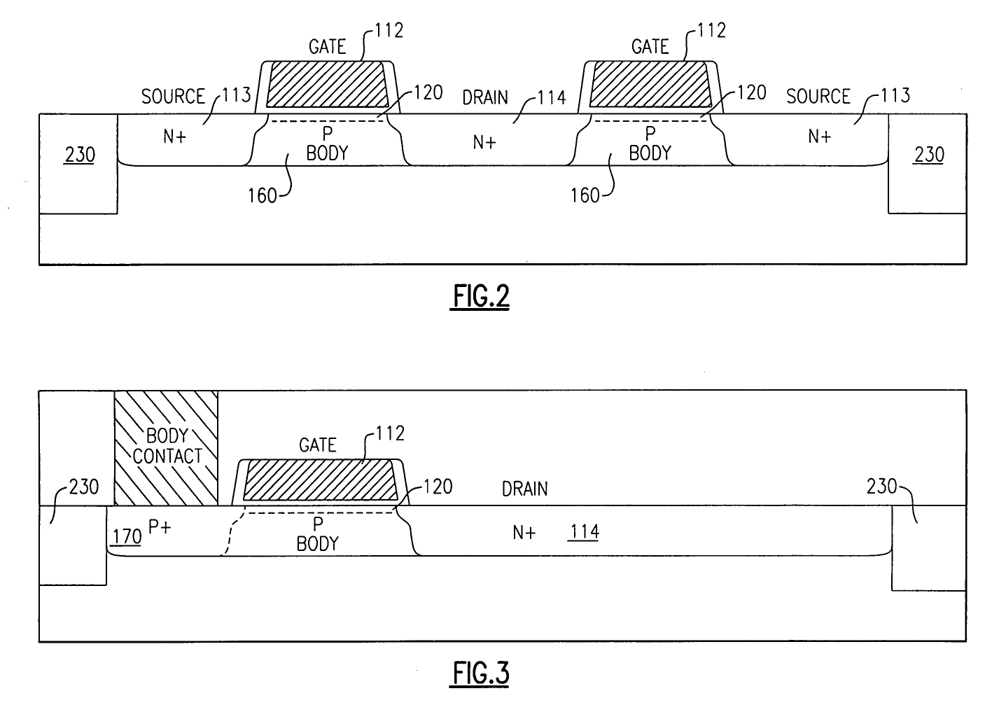

Referring to FIGS. 5 and 6 again, the embodiments describe herein address problems present in the prior art. For one, the portion of the gate conductor stack 515 that is not part of the active transistor 500 is greatly reduced relative to that shown in the prior art transistors shown in FIGS. 1 and 4. In addition, the annular shape of the gate conductor in FIG. 5 makes it tolerant to overlay errors. The design of FIG. 5 can be moved up or down in relation to the length of the active area without affecting the length of the gate conductor in contact with the active area, and hence, without affecting the current drive of the transistor.

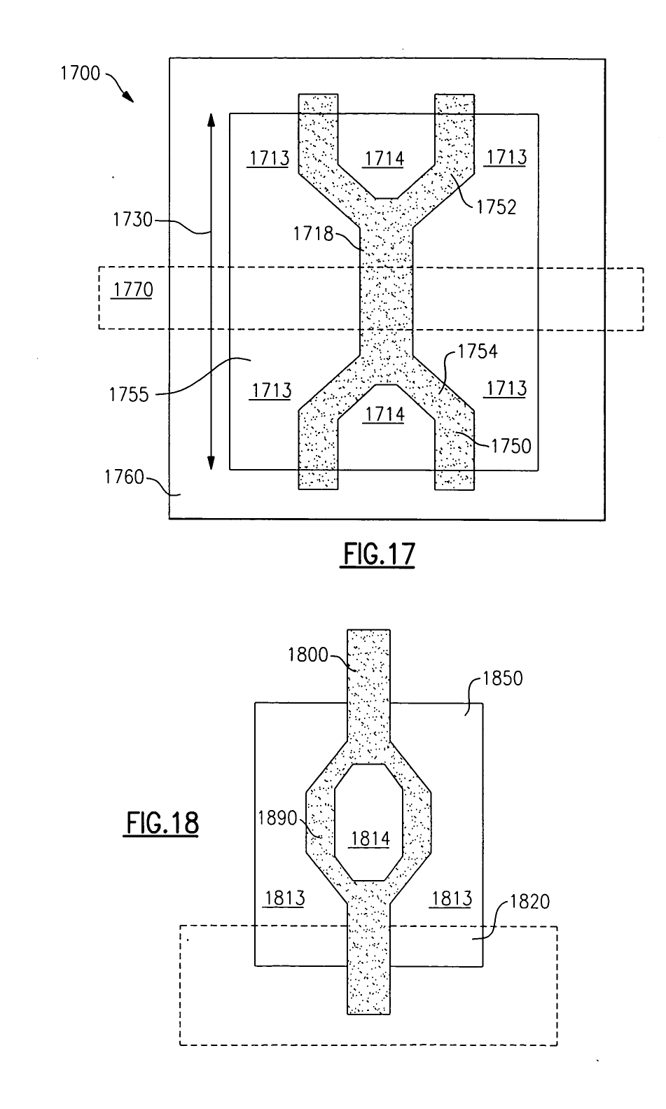

Other embodiments of the invention provide similar advantages to those discussed in relation to the embodiments depicted in FIGS. 5 and 6. One such alternative embodiment is illustrated in FIG. 17. FIG. 17 is a top down view of an a transistor according to another embodiment in which a pair of multiple-finger portions are provided in place of the annular portion of the gate conductor as shown and described above relative to FIGS. 5 and 6. As shown in FIG. 17, the transistor 1700 is formed in an active area 1755 bounded by trench isolations 1760. A gate conductor 1750 separates a source 1713 of the transistor from a drain 1714. The gate conductor 1750 overlies the channel (not shown). The gate conductor includes a first multiple finger pattern 1752. A connecting pattern 1718 conductively connects the first multiple finger pattern 1752 to a second multiple finger pattern 1754. In variations of the embodiment, more than two fingers, for example 4, 6, 8 or more fingers are provided in each multiple-finger pattern. Preferably, the number of fingers is kept to an even number for ease of fabrication. An electrically conductive body contact 1770 is disposed in the vicinity of the connecting pattern 1718. When the transistor is an NFET, a body contact is formed having a p+ doping. Alternatively, when the transistor is a PFET, a body contact having an n+ doping is formed.

Like the embodiment shown and described above with respect to FIGS. 5 and 6, this embodiment is tolerant to overlay error. Each of the two multiple-finger patterns 1750, 1752 of the gate conductor extend from the active area 1755 onto the trench isolation region 1760. As a result, overlay error which results in the patterns 1752, 1754 being shifted in a direction of the length 1730 of the active area 1755 does not result in the transistor 1700 having a smaller or greater length of the gate conductor in contact with the active area 1755. For example, assume that the gate conductor 1750 is shifted downward in the lengthwise direction of active area 1755. In such case, pattern 1754 is shifted downward, causing it to have a shorter length in contact with the active area 1755. However, the opposite is true for pattern 1752, which at the same time acquires a longer length in contact with the active area. Hence, while a first pattern 1754 becomes effectively shorter over the active area, this is compensated by the second pattern which becomes longer over the active area. Because the effective length of the gate conductor has not changed, the net result is no change in the current drive of the transistor due to overlay error.

Yet another embodiment of the invention is illustrated in FIG. 18. This embodiment is similar to that of FIG. 5 and has similar advantages. In this embodiment, an extension 1800 is added to the top of the gate conductor pattern 1890. The source and drain regions are shown at 1813 and 1814, respectively, and the body contact is shown at 1820. The embodiment of FIG. 18 can also be used both with an NFET in conjunction with a p+ body contact or a PFET in conjunction with an NFET body contact.

The embodiments of FIGS. 5, 17 and 18 have certain common features in that they are more tolerant to overlay error, since the patterns can be shifted up or down over the active area, without changing the amount of current drive provided by the transistor. In addition, the area of inactive portion of the gate conductor stack is reduced, helping to lower capacitance.

While the invention has been described in accordance with certain preferred embodiments thereof, those skilled in the art will understand the many modifications and enhancements which can be made thereto without departing from the true scope and spirit of the invention, which is limited only by the claims appended below.

1. An insulated gate field effect transistor, comprising:
a source, a drain, and channel formed in a layer of a single-crystal semiconductor;
said layer disposed over and insulated from a bulk semiconductor layer of a substrate by a buried insulator layer;
a gate conductor disposed in an annular pattern overlying said channel, such that said gate conductor surrounds one of said source and said drain disposed to the inside of said annular pattern, the other of said source and said drain being disposed to the outside of said annular pattern, said gate conductor further including a second pattern connected to said annular pattern; and
a conductive body contact to said single-crystal semiconductor layer disposed in the vicinity of said second pattern.

2. The insulated gate field effect transistor of claim 1, wherein said source, drain and channel region are disposed in an active area of said layer bounded by one or more isolation structures.

3. The insulated gate field effect transistor of claim 1, wherein said second pattern extends linearly between said annular pattern and an edge of said active area.

4. The insulated gate field effect transistor of claim 1, wherein said annular pattern includes a pair of parallel portions oriented in a first direction substantially parallel to an edge of said active area and further includes angled portions oriented at an angle to said first direction.

5. The insulated gate field effect transistor of claim 4, wherein at least some of said angled portions are oriented at angles between about 30 degrees and 60 degrees with respect to said first direction.

6. The insulated gate field effect transistor of claim 4, wherein at least some of said angled portions are oriented at angles of about 45 degrees.

7. The insulated gate field effect transistor of claim 1, wherein said transistor is an n-type FET, the source is disposed to the outside of the annular pattern, and the body contact is disposed on a region of said layer adjacent to said source.

8. The insulated gate field effect transistor of claim 1, wherein said gate conductor further includes a third pattern connected to said annular pattern, said second and third patterns extending from first and second locations of said annular pattern in substantially opposite directions.

9. The insulated gate field effect transistor of claim 8, wherein said second and said third patterns extend linearly between said annular pattern and edges of said active area.

10. An insulated gate field effect transistor, comprising:
a source, a drain, and channel formed in a layer of a single-crystal semiconductor,
said layer disposed over and insulated from a bulk semiconductor substrate by a buried insulator layer;
a gate conductor including a first multiple finger pattern overlying said channel and a second multiple finger pattern overlying said channel, and a connecting pattern conductively connecting said first and second multiple finger patterns; and
an electrically conductive body contact to said single-crystal semiconductor layer disposed in the vicinity of said connecting pattern.

11. The insulated gate field effect transistor of claim 10, wherein said first and said second multiple finger patterns each have two fingers, wherein one of said source and said drain is disposed between said two fingers, and the other of said source and said drain is disposed to the outside of said two fingers.

12. The insulated gate field effect transistor of claim 10 wherein said gate conductor includes four fingers.

13. The insulated gate field effect transistor of claim 10 wherein said gate conductor includes a multiple n of two fingers, wherein n is greater than two.

14. The insulated gate field effect transistor of claim 10, wherein said source, drain and channel region are disposed in an active area of said layer bounded by one or more isolation structures.

15. The insulated gate field effect transistor of claim 10, wherein said transistor is an n-type FET, and said source is disposed to the outside of the annular pattern, and the body contact is disposed on a region of said layer adjacent to said source.

16. A method of making an insulated gate field effect transistor, comprising:
providing a substrate having a single-crystal semiconductor layer separated from a bulk semiconductor portion by a buried insulator layer;
forming a source, a drain, and a channel in said single-crystal semiconductor layer;
forming a gate conductor disposed in an annular pattern overlying said channel, such that said gate conductor surrounds one of said source and said drain disposed to the inside of said annular pattern, the other of said source and said drain being disposed to the outside of said annular pattern, said gate conductor further including a second pattern connected to said annular pattern; and
forming an electrically conductive contact to said single-crystal semiconductor layer in the vicinity of said second pattern.

17. The method of claim 16 wherein said gate conductor is patterned to form said annular pattern and said second pattern prior to depositing at least one material selected from the group consisting of heavily doped polysilicon, metals and metal compounds to form said electrically conductive contact.

18. The method of claim 17 wherein said material is deposited prior to implanting ions to form said source, and said drain, said channel remaining as an area disposed under at least portions of said gate conductor between said source and said drain.

19. The method of claim 15, further comprising:
patterning an active area in said single-crystal semiconductor layer;
providing trench isolations to isolate said active area,
wherein said source, said drain, and said channel are formed in said active area.

20. The method of claim 15, wherein said second pattern extends linearly between said annular pattern and an edge of said active area.
